(19) United States
(12) Patent Application Publication
(10) Pub. No.: US 2024/0314955 A1
(43) Pub. Date: Sep. 19, 2024

(54) DISPLAY PANEL AND DISPLAY DEVICE

(71) Applicant: XIAMEN TIANMA DISPLAY TECHNOLOGY CO., LTD., Xiamen (CN)

(72) Inventors: Zhiwei WANG, Xiamen (CN); Mengting CHEN, Xiamen (CN)

(73) Assignee: XIAMEN TIANMA DISPLAY TECHNOLOGY CO., LTD., Xiamen (CN)

(21) Appl. No.: 18/676,531

(22) Filed: May 29, 2024

(30) Foreign Application Priority Data
Dec. 18, 2023 (CN) 202311743654.9

(51) Int. Cl. H05K 5/03; G02B 5/00; G02B 5/08

(52) U.S. Cl. CPC H05K 5/03; G02B 5/003; G02B 5/08

(57) ABSTRACT

A display panel and a display device are provided. The display panel includes a cover plate and a display module; the cover plate is located on a light-exiting side of the display module; an optical film is provided on a back surface of the display module and/or a sidewall of the display module; an encapsulant is provided at an edge of the display module to encapsulate the edge of the display module with the cover plate. The optical film causes a light reflection intensity at the back surface of the display module to be different from a light reflection intensity at the sidewall of the display module.

This application claims priority to Chinese Patent Application No. 202311743654.9, titled “DISPLAY PANEL AND DISPLAY DEVICE”, filed on Dec. 18, 2023 with the China National Intellectual Property Administration, which is hereby incorporated by reference in its entirety.

### FIELD

The present disclosure relates to the field of display technologies, and in particular to a display panel and a display device.

### BACKGROUND

External water vapor and grease that enter internal films of a display module through an edge of the display module affect the display effect of the display module. Therefore, an encapsulant is generally provided at an edge of the display module to encapsulate and protect the display module, to prevent failure of the display module due to the invasion of the external water vapor and grease, to improve reliability of the display module.

After the encapsulant is provided, the encapsulation effect needs to be monitored to ensure that the encapsulant effectively protects the display module. In the conventional technology, an edge of the display module is generally used as a reference edge to determine whether widths of the encapsulant on both sides of the edge of the display module meet a process standard. The edge of the display module generally refers to a connection between a back surface and a sidewall of the display panel. If the width of the encapsulant exceeds the process standard, the encapsulant is considered as unqualified. However, the encapsulant covering a surface of the display module causes difficulty in recognizing the edge of the display module, since gray scales on both sides of the edge of the display module are close to each other, and gray scales of images of both sides of the edge obtained through the AOI (Automated Optical Inspection) technology are similar and difficult to distinguish, which causes difficulty in determining the edge of the display module. Therefore, when monitoring the encapsulation effect, it is difficult to monitor whether the encapsulant on the display module is qualified.

### SUMMARY

A display panel and a display device are provided according to embodiments of the present disclosure.

In one embodiment, a display panel is provided according to an embodiment of the present disclosure. The display panel includes: a cover plate and a display module; where the cover plate is located on a light-exiting side of the display module; an optical film is provided on a back surface of the display module and/or a sidewall of the display module; an encapsulant is provided at an edge of the display module to encapsulate the edge of the display module with the cover plate; and the optical film causes a light reflection intensity at the back surface of the display module to be different from a light reflection intensity at the sidewall of the display module.

In another embodiment, a display device is provided according to an embodiment of the present disclosure. The display device includes the display panel as described in the embodiments.

### BRIEF DESCRIPTION OF THE DRAWINGS

Drawings, which are incorporated in and constitute a part of this specification, illustrate embodiments of the present disclosure and serve to explain principles of the present disclosure together with the specification.

In order to illustrate the embodiments of the present disclosure or clearly, the drawings in the specification of the embodiments are briefly introduced below.

FIG. 1 is a schematic structural diagram of a display panel according to an embodiment of the present disclosure.

FIG. 2 is a schematic structural diagram of a film structure along an AA′ direction of the display panel shown in FIG. 1 according to an embodiment of the present disclosure.

FIG. 3 is a grayscale image obtained by performing AOI detection on an encapsulant of a display panel according to an embodiment of the present disclosure.

FIG. 4 is a schematic structural diagram of a film structure along the AA′ direction of the display panel shown in FIG. 1 according to another embodiment of the present disclosure.

FIG. 5 is a grayscale image obtained by performing AOI detection on an encapsulant of a display panel according to another embodiment of the present disclosure.

FIG. 6 is a schematic structural diagram of a film structure along the AA′ direction of the display panel shown in FIG. 1 according to another embodiment of the present disclosure.

FIG. 7 is a grayscale image obtained by performing AOI detection on an encapsulant of a display panel according to another embodiment of the present disclosure.

FIG. 8 is a schematic structural diagram of a film structure along the AA′ direction of the display panel shown in FIG. 1 according to another embodiment of the present disclosure.

FIG. 9 is a schematic structural diagram of a film structure along the AA′ direction of the display panel shown in FIG. 1 according to another embodiment of the present disclosure.

FIG. 10 is a schematic structural diagram of a film structure of a flat display panel according to an embodiment of the present disclosure.

FIG. 11 is a schematic structural diagram of a film structure of a flat display panel according to another embodiment of the present disclosure.

FIG. 12 is a schematic structural diagram of a film structure of a flat display panel according to another embodiment of the present disclosure.

FIG. 13 is a schematic structural diagram of a film structure of a flat display panel according to another embodiment of the present disclosure.

FIG. 14 is a schematic structural diagram of a film structure along the AA′

direction of the display panel shown in FIG. 1 according to another embodiment of the present disclosure.

FIG. 15 is a schematic structural diagram of a display device according to an embodiment of the present disclosure.

In the drawings:

| | |
|---|---|
| 10: | cover plate; |
| 20: | display module; |
| 30: | optical film; |
| 40: | encapsulant; |
| 201: | back surface; |
| 202: | sidewall; |
| 21: | optical adhesive layer; |
| 22: | polarizer; |
| 23: | display light-emitting layer; |
| 24: | adhesive layer; |
| 25: | supporting layer; |
| 26: | protective layer; |
| 31: | opening structure. |

### DETAILED DESCRIPTION

In order to understand the embodiments of the present disclosure clearly, the solutions of the present disclosure are further described below. It should be noted that, embodiments of the present disclosure and features in the embodiments can be combined with each other as long as there is no conflict.

Many specific details are set forth in the following description to fully understand the present disclosure, but the present disclosure can also be implemented in other ways different from those described here. Apparently, embodiments in the description are only a part, not all of the embodiments of the present disclosure.

For a display panel, such as an OLED (Organic Light Emitting Diode) display panel, a display module of the display panel is directly related to a display effect of the display panel. External water vapor and grease entering a film structure of the display module through an edge of the display module affect the display effect of the display module. Therefore, an encapsulant is provided at the edge of the display module to encapsulate and protect the display module, to prevent failure of the display module due to the invasion of the external water vapor and grease, to improve reliability of the display module.

After the encapsulant is provided, the encapsulation effect needs to be monitored to ensure that the encapsulant effectively protects the display module. Generally, an edge of the display module (which is a connection between a back surface and a sidewall of the display panel) is used as a reference edge to determine whether widths of the encapsulant on both sides of the reference edge meet a process standard. A large width of the encapsulant may affect other positions of the display panel; and a small width of the encapsulant may lead to incomplete encapsulation and poor protection, which causes reduced reliability of the display panel. In a case that the encapsulant is too wide or too narrow, which does not meet the process standard, the encapsulant can be determined to be unqualified.

The encapsulant covering a surface of the display module causes difficulty in recognizing the edge of the display module, since gray scales on both sides of the edge of the display module are close to each other, and the gray scales of images of both sides of the edge obtained through the AOI technology are similar and difficult to distinguish, which causes difficulty in determining the edge of the display module. Therefore, when monitoring the encapsulation effect, it is difficult to monitor whether the encapsulant is qualified.

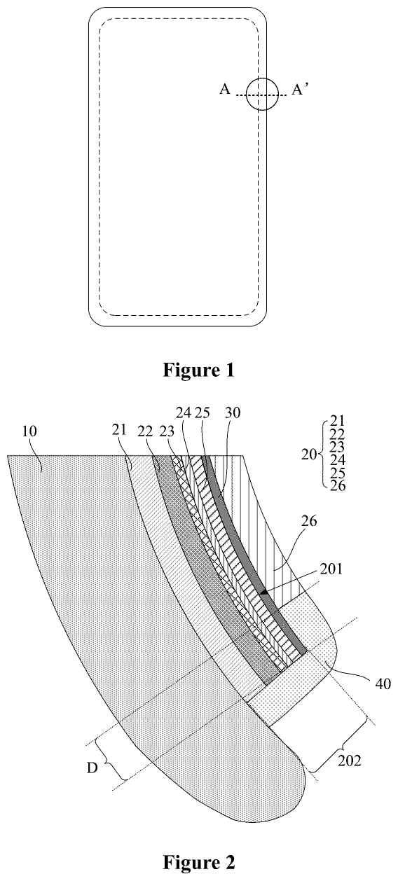

In order to solve the above problem, an embodiment of the present disclosure provides a display panel. FIG. 1 shows a display panel according to an embodiment of the present disclosure. FIG. 2 is a schematic structural diagram of a film structure along an AA′ direction of the display panel shown in FIG. 1 according to an embodiment of the present disclosure. Reference is made to FIG. 1 and FIG. 2, the display panel includes: a cover plate 10 and a display module 20. The cover plate 10 is located on a light-exiting side of the display module 20. An optical film 30 is provided on a back surface 201 of the display module 20 and/or a sidewall 202 of the display module 20. An encapsulant 40 is provided at an edge of the display module 20 to encapsulate the edge of the display module 20 with the cover plate 10. The optical film 30 causes a light reflection intensity at the back surface 201 of the display module 20 to be different from a light reflection intensity at the sidewall 202 of the display module 20 back.

The display panel includes a cover plate 10 and a display module 20. The cover plate 10 plays a protective and supporting role in the display panel. The display module 20 displays by emitting light in the display panel. Therefore, the display module 20 includes a light-exiting side and a back surface, and the cover plate 10 is located on the light-exiting side of the display module 20. The edge of the display module 20 may be in contact with the external environment. Water vapor and grease in the external environment that enter the internal films of the display module 20 from the edge of the display module 20 affect the performance of the display module 20 and the display effect of the display panel. In order to prevent the failure of the display module 20 caused by the intrusion of external water vapor and grease, the encapsulant 40 is provided at the edge of the display module 20 to encapsulate the edge of the display module 20 with the cover plate 10, to isolate the display module 20 from the external environment.

After the encapsulant 40 is provided, it is necessary to monitor the encapsulation effect to determine whether the encapsulant is qualified, to ensure that the encapsulant can effectively protect the display module 20. Generally, the edge of the display module 20 is used as the reference edge, and then it is determined whether the widths of the encapsulant 40 on the left and right sides of the edge of the display module 20 meet the process standard. The left and right sides of the edge of the display module 20 are respectively the back surface 201 of the display module 20 and the sidewall 202 of the display module 20.

Since the edge of the display module 20 is covered after the encapsulant 40 is provided, grayscale images detected by using the AOI technology at the back surface 201 of the display module 20 and the sidewall 202 of the display module 20 that are adjacent to the edge of the display module 20, has a low contrast and a small gray scale difference. Correspondingly, the connection between the back surface 201 of the display module 20 and the sidewall 202 of the display module 20 (that is, the edge of the display module 20) is not recognizable, resulting in difficulty in determining the edge of the display module 20. Based on the above, in the display panel according to an embodiment of the present disclosure, the optical film 30 is provided on the back surface 201 of the display module 20 and/or the sidewall 202 of the display module 20. A position with the optical film 30 and a position without the optical film 30 have different light reflection intensities, which increases the contrast of the grayscale images detected by using the AOI technology, and the connection between the back surface 201 of the display module 20 and the sidewall 202 of the display module 20 can be recognized, and the edge of the display module 20 can be accurately positioned.

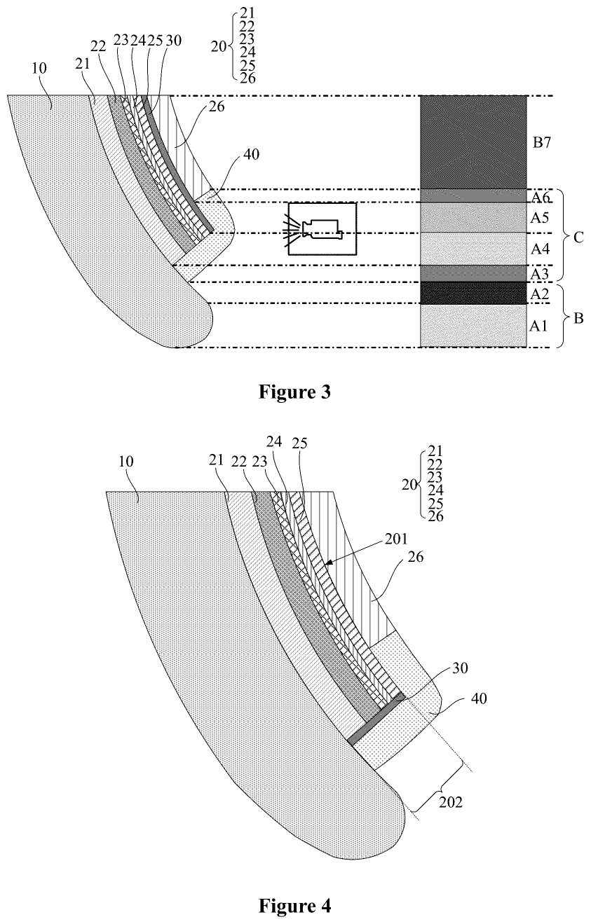

FIG. 3 is a grayscale image obtained by performing AOI detection on an encapsulant of a display panel according to an embodiment of the present disclosure. Reference is made to FIGS. 2 and 3, the optical film 30 is provided on the back surface 201 of the display module 20, the encapsulant 40 is provided on the back surface 201 of the display module 20 and the sidewall 202 of the display module 20. When a detecting light source irradiates the display panel, the back surface 201 of the display module 20 and the sidewall 202 of the display module 20 have different light reflection intensities, and the grayscale images detected by using the AOI technology has different grayscale values and a large contrast, and the edge of the display module 20 is easily recognizable. For example, A4 represents a grayscale image detected by using AOI corresponding to the sidewall 202 of the display module 20, which is provided with the encapsulant 40 and is not provided with the optical film 30; and A5 represents a grayscale image detected by using AOI corresponding to a position of the back surface 201 of the display module 20, at which the encapsulant 40 and the optical film 30 are provided. The grayscale value of A4 is significantly different from the grayscale value of A5. Therefore, even in the case that the encapsulant 40 is provided on the back surface 201 and the sidewall 202 of the display module 20, the grayscale value of A4 is significantly different from the grayscale value of A5, and the connection between A4 and A5 can be recognized. That is, the edge of the display module can be recognized accurately.

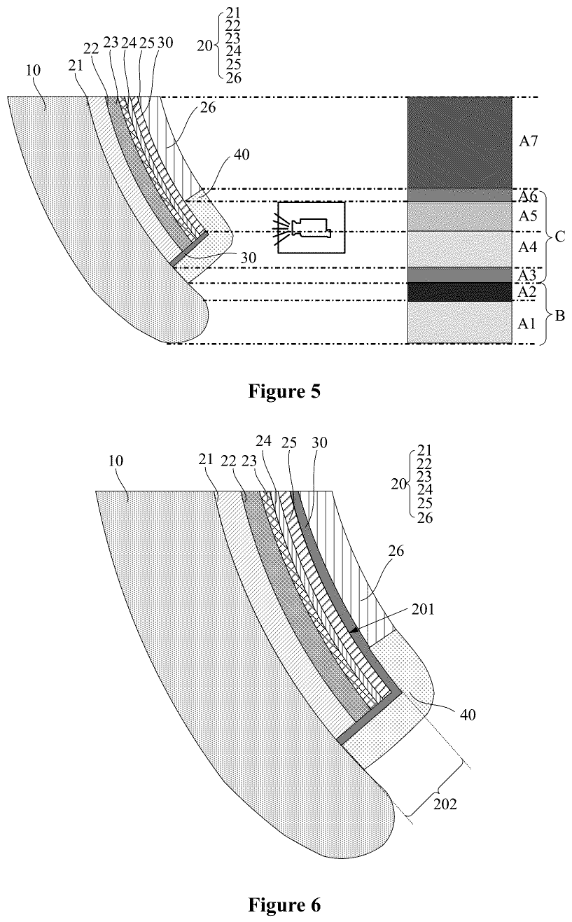

FIG. 4 is a schematic structural diagram of a film structure along the direction AA′ of the display panel shown in FIG. 1 according to another embodiment of the present disclosure. FIG. 5 is a grayscale image obtained by performing AOI detection on an encapsulant of a display panel according to another embodiment of the present disclosure. Reference is made to FIGS. 4 and 5, the optical film 30 is provided on the sidewall 202 of the display module 20, the encapsulant 40 is provided on both ends of the back surface 201 of the display module 20 and the sidewall 202 of the display module 20. When the detecting light source irradiates the display panel, the back surface 201 of the display module 20 and the sidewall 202 of the display module 20 have different light reflection intensities, and the grayscale images detected by using the AOI technology have different grayscale values and large contrast, and the edge of the display module 20 is easily recognizable. For example, A4 represents the grayscale image detected by using AOI corresponding to the sidewall 202 of the display module 20, where the optical film 30 is provided; and A5 represents the grayscale image detected by using AOI corresponding to a position of the back surface 201 of the display module 20, at which the encapsulant 40 is provided and the optical film 30 is not provided. The grayscale value of A4 is significantly different from the grayscale value of A5. Even in the case that the encapsulant 40 is provided on the back surface 201 and the sidewall 202 of the display module 20, there is a large difference between the grayscale values of A4 and A5, and the connection between A4 and A5 can be clearly recognized, that is, the edge of the display module can be accurately recognized.

A position of the display panel covered by the encapsulant 40 and a position of the display panel not covered by the encapsulant 40 have different light reflection intensities. Positions of the display panel with different curvatures and different materials also have different light reflection intensities. For example, A1 represents a grayscale image detected by using AOI corresponding to an upward bend of the cover plate 10, where no optical film 30 is provided. A2 represents a grayscale image detected by using AOI corresponding to a flat position of the cover plate 10. A1 and A2 have different grayscale values. B represents a grayscale image (including A1 and A2) corresponding to a part of the cover plate 10 without the encapsulant 40. A3 represents a grayscale image detected by using AOI corresponding to a part of the cover plate 10 provided with the encapsulant 40 and no optical film. A6 represents the grayscale image detected by using AOI corresponding to the sidewall of the protective layer 26 provided with the encapsulant 40 and no optical film. The grayscale values of A3 to A6 are different. C represents the grayscale image (including A3 to A6) corresponding to parts of the display panel where the encapsulant 40 is provided. The grayscale values of the above grayscale images are different. Therefore, according to the grayscale values, parts of the display panel provided with the encapsulant 40 may be determined, and the width and position of the encapsulant 40 may be accurately determined when combining with the edge of the display module 20, to monitor the encapsulation effect.

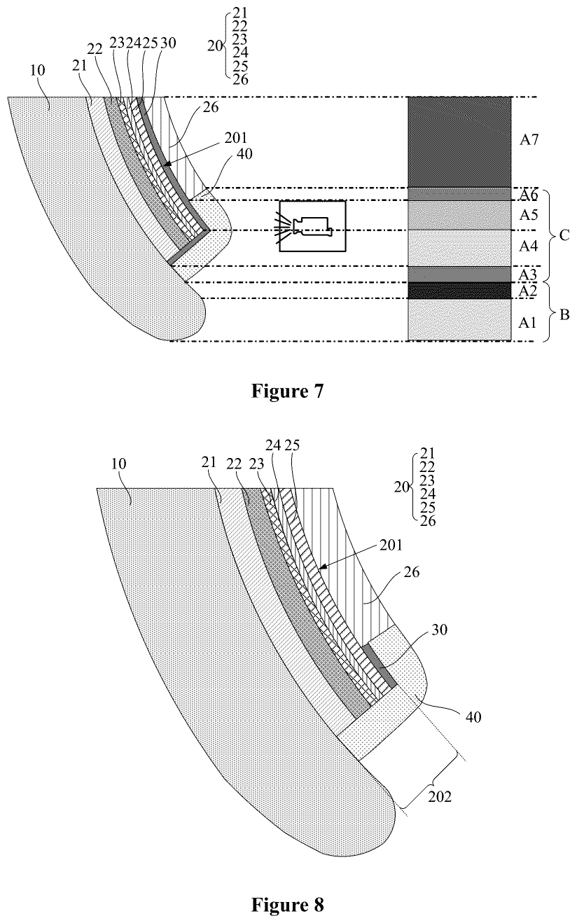

FIG. 6 is a schematic structural diagram of a film structure along the AA′ direction of the display panel shown in FIG. 1 according to another embodiment of the present disclosure. FIG. 7 is a grayscale image obtained by performing AOI detection on an encapsulant of a display panel according to another embodiment of the present disclosure. Referring to FIGS. 6 and 7, the optical film 30 is provided on both the back surface 201 of the display module 20 and the sidewall 202 of the display module 20. The encapsulant 40 is provided on both ends of the back surface 201 of the display module 20 and the sidewall 202 of the display module 20. Since the film on the back surface 201 of the display module 20 is formed by deposition, and the sidewall 202 of the display module 20 is formed by cutting, a flatness of the back surface 201 of the display module 20 is better than a flatness of the sidewall 202 of the display module 20. Due to the different flatness of the back surface 201 and the sidewall 202, in a case that the back surface 201 of the display module 20 and the sidewall 202 of the display module 20 are both provided with the optical film 30, the light reflection intensities at the back surface 201 and the sidewall 202 are still different. Therefore, the grayscale images detected by using the AOI technology are different, and there is a significant difference between the grayscale values of the grayscale images. Correspondingly, the edge of the display module 20 is easily recognizable. A4 represents the grayscale image detected by using AOI corresponding to the sidewall 202 of the display module 20, at which the encapsulant 40 and the optical film 30 are provided. A5 represents the grayscale image detected by using AOI corresponding to a position of the back surface 201 of the display module 20, where the encapsulant 40 and the optical film 30 are provided. The grayscale value of A4 is significantly different from the grayscale value of A5. Even in the case that the encapsulant 40 is provided at the edge of the display module 20, the difference between grayscale values of A4 and A5 is significant. Therefore, the connection between A4 and A5 can be clearly recognized, that is, the edge of the display module can be accurately recognized.

The foregoing content only explains partial structures or partial films related to the embodiments of the present disclosure. The display panel may further include some other film structures related to functions of the display panel.

Reference is made to FIGS. 2 to 7, in other embodiments, the display module 20 includes an optical adhesive layer 21, a polarizer 22, a display light-emitting layer 23, an adhesive layer 24, a supporting layer 25, and a protective layer 26, functions of which are explained in subsequent embodiments. In some embodiments, other films may also be included, which are not limited herein, and the above are only examples.

In an embodiment, an optical film is provided on the back surface of the display module and/or the sidewall of the display module. The optical film causes the back surface of the display module and the sidewall of the display module to have different light reflection intensities, resulting in a large contrast between the back surface and the sidewall. Correspondingly, the edge of the display panel is recognizable, and the edge of the display module can be accurately positioned. Accurate positioning of the edge of the display module facilitates monitoring of the encapsulation effect and determination of whether the encapsulant is qualified. With the embodiments of the present disclosure, the contrast between the back surface and the sidewall of the display module can be improved and the edge of the display module can be positioned accurately, to monitor whether the encapsulant of the display module is qualified.

In some embodiments, reference is made to FIGS. 2 to 7, the optical film 30 includes a reflective layer.

When the optical film 30 is the reflective layer and the detecting light source irradiates the display module 20, strong reflection may occur at the position where the optical film 30 is provided, the reflection intensity is large, and the corresponding grayscale image has a large grayscale value; while the reflection intensity at the position without the optical film 30 is small, and the corresponding grayscale image has a small grayscale value. Therefore, the reflective layer increases the difference between grayscale values of the grayscale images corresponding to the back surface 201 and the sidewall 202, which facilitates recognition of the edge of the display module 20.

Reference is made to FIG. 3, when the optical film 30 (reflective layer) is provided on the back surface 201 of the display module 20, the back surface 201 has a large light reflection intensity, and the grayscale value of the grayscale image (A5) corresponding to a position of the back surface 201 with the encapsulant 40 is large. The sidewall 202 of the display module 20 is not provided with the optical film 30 and has a small light reflection intensity, and the grayscale value of the corresponding grayscale image (A4) is small. Therefore, there is a significant difference between the grayscale values of the grayscale images detected by using the AOI technology at the position of the back surface 201 of the display module 20 where the encapsulant 40 is provided and the sidewall 202. Correspondingly, the edge of the display module can be accurately recognized. Reference is made to FIG. 5, when the optical film is provided on the sidewall 202 of the display module 20, the sidewall 202 has a large light reflection intensity, and the grayscale value of the grayscale image (A4) corresponding to the sidewall 202 is large; while the optical film 30 is not provided on the back surface 201 of the display module 20, the back surface 201 has a small light reflection intensity, the grayscale value of the grayscale image (A5) corresponding to the position of the back surface 201 provided with the encapsulant 40 is relatively small. Therefore, there is a significant difference between the grayscale values of the grayscale images detected by using AOI technology at the position of the back surface 201 of the display module 20 where the encapsulant 40 is provided and the sidewall 202. Correspondingly, the edge of the display module 20 can be accurately recognized. Reference is made to FIG. 7, the optical film 30 is provided on the back surface 201 and the sidewall 202 of the display module 20. The light reflection intensities at the back surface 201 and the sidewall 202 both increase. However, the flatness of the back surface 201 is different from the flatness of the sidewall 202. The back surface 201 is relatively flat, and may have strong reflection when exposed to light, where most of reflected light is received by the detection device, and the grayscale value of the grayscale image (A5) corresponding to the position of the back surface 201 provided with the encapsulant 40 is large; while the surface of the sidewall 202 is uneven and has diffuse reflection when exposed to light, where the light may be reflected in all directions, and only a part of the light is received by the detection device, and the grayscale value of the grayscale image (A4) corresponding to the sidewall 202 is small. Therefore, with improvement in the brightness of the back surface 201 and sidewall 202 of the display module 20, there is a significant difference between the grayscale values of the grayscale images detected by using AOI technology at the position of the back surface 201 of the display module 20 where the encapsulant 40 is provided and the sidewall 202 of the display module 20. Accordingly, the edge of the display module 20 can be accurately recognized.

In some embodiments, FIG. 8 is a schematic structural diagram of a film structure along the AA′ direction of the display panel shown in FIG. 1 according to another embodiment of the present disclosure. Reference is made to FIG. 8, the optical film 30 is the reflective layer, and the reflective layer covers at least a part of the back surface 201 of the display module 20, and the edge of the reflective layer is flush with the edge of the display module 20.

In an embodiment, the reflective layer may cover at least a part of the back surface 201 of the display module 20, and the edge of the reflective layer is flush with the edge of the display module 20. That is, the edge of the reflective layer is flush with the connection between the back surface 201 and the sidewall 202 of the display module 20. The position provided with the reflective layer has a large light reflection intensity. However, the sidewall 202 of the display module 20 is not provided with the reflective layer, and has a small light reflection intensity. With the above structure, when the detecting light source irradiates the display panel, the sidewall 202 of the display module 20 and the back surface 201 of the display module 20 have different light reflection intensities. There is a significant difference between the grayscale values of the grayscale images detected by using AOI technology at the position of the back surface 201 of the display module 20 where the reflective layer is provided and the sidewall 202. The grayscale value of the grayscale image corresponding to the sidewall 202 is small, and the grayscale value of the grayscale image corresponding to the position of the back surface 201 provided with the reflective layer is large, thus the difference between grayscale values of the two grayscale images is large. Correspondingly, the edge of the display module 20 can be accurately recognized. In some embodiments, reference is made to FIG. 2, the reflective layer covers the entire back surface 201 of the display module 20, and the edge of the reflective layer is flush with the edge of the display module 20, and the edge of the display module 20 can be accurately recognized.

It is to be noted that, the range of the at least part of the back surface 201 of the display module 20 covered by the reflective layer is not limited in the embodiments of the present disclosure, but the edge of the reflective layer is to be flush with the edge of the display module 20, to facilitate comparison between the back surface 201 and the sidewall 202 without the reflective layer.

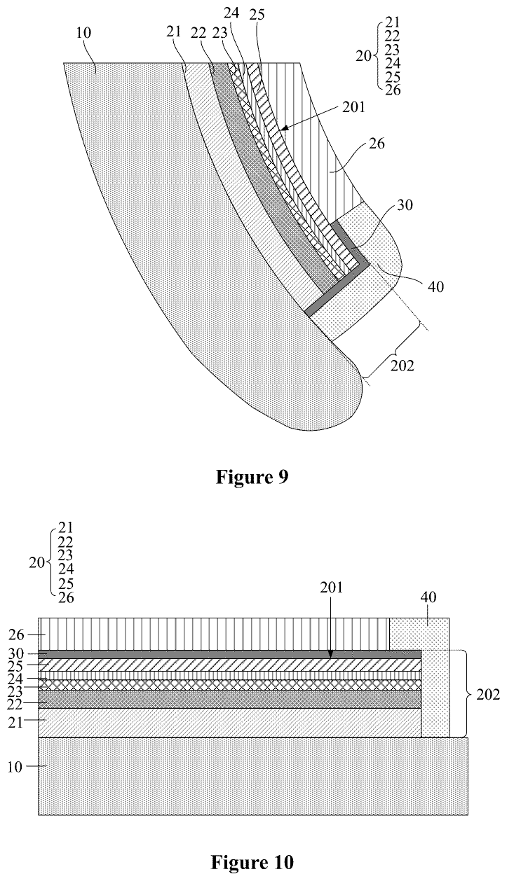

In some embodiments, reference is made to FIG. 9, which is a schematic structural diagram of a film structure along the AA′ direction of the display panel shown in FIG. 1 according to another embodiment of the present disclosure. The optical film 30 is the reflective layer, and the reflective layer covers at least a part of the back surface 201 of the display module 20 and covers the sidewall 202 of the display module 20.

In an embodiment, the reflective layer may cover at least a part of the back surface 201 of the display module 20 and the sidewall 202 of the display module 20. Both the back surface 201 and the sidewall 202 of the display module 20 are provided with the reflective layer, and the reflection intensities at both the back surface 201 and the sidewall 202 increase. However, the flatness of the back surface 201 is different from the flatness of the sidewall 202. The back surface 201 is relatively flat and has strong reflection when exposed to light, and the grayscale value of the grayscale image corresponding to the position of the back surface 201 where the reflective layer is provided is large; while the surface of the sidewall 202 is uneven, which causes diffuse reflection when irradiated by light, and the grayscale value of the grayscale image corresponding to the sidewall 202 is small. Therefore, there is a significant difference between the grayscale values of the grayscale images detected by using the AOI technology at the position of the back surface 201 of the display module 20 where the reflective layer is provided and the sidewall 202. Correspondingly, the edge of the display module 20 can be recognized accurately.

In some embodiments, reference is made to FIGS. 4 and 5, the optical film 30 in FIGS. 4 and 5 includes the reflective layer, a side of the display panel is bent toward the back surface 201, and the reflective layer covers the sidewall 202 of the display module 20.

The side of the display panel is bent toward the back surface 201. For example, the display panel is a curved screen, to achieve narrow bezel, expand the screen-to-body ratio, and even achieve a borderless front view. When the display panel is of this type, the reflective layer may cover only the sidewall 202 of the display module 20. Since the side of the display panel is bent toward the back surface 201, when the detecting light irradiates the back surface 201 of the display module 20 from the side of the back surface 201 of the display module 20, the sidewall 202 of the display module 20 may also be irradiated. The sidewall 202 of the display module 20 is covered with the reflective layer and has a large light reflection intensity, and most of the reflected light is received by the detection device, and the grayscale value of the grayscale image of the sidewall 202 is large; while the back surface 201 of the display module 20 is not covered with the reflective layer and has a small light reflection intensity, and the detection device receives less reflected light, and the grayscale value of the grayscale image of the back surface 201 is small. Therefore, there is a significant difference between the grayscale values of the grayscale images detected by using the AOI technology at the back surface 201 and the sidewall 202 of the display module 20. Correspondingly, the edge of the display module 20 can be recognized accurately.

In an embodiment, reference is made to FIGS. 2 to 7, in an application scenario where the optical film 30 includes the reflective layer and the side of the display panel is bent toward the back surface 201, the difference between the grayscale values of the grayscale images of the back surface 201 and the sidewall 202 of the display module 20 may be increased in various manners, including arranging the reflective layer on the back surface 201 of the display module 20, arranging the reflective layer on the sidewall 202 of the display module 20, or arranging the reflective layer on both the back surface 201 and the sidewall 202 of the display module 20. The above various manners of arranging the reflective layer enhance the difference between grayscale values of the grayscale images of the back surface 201 and sidewall 202 of the display module 20, to accurately recognize the edge of the display module 20.

In some other embodiments, reference is made to FIG. 10, which is a schematic structural diagram of a film structure of a flat display panel according to an embodiment of the present disclosure, the display panel is a flat display panel, such as a flat screen, and the sides of the display panel are planar structure. With this structure, when the detecting light irradiates the back surface 201 of the display module 201 from the side of the back surface 201 of the display module 20, only the back surface 201 of the display module 20 is irradiated, and the sidewall 202 of the display module 20 is not irradiated. The optical film 30 may be provided on the back surface 201 of the display module 20 to detect the edge of the display module 20 of the flat display panel. The encapsulant 40 is provided at the edge of the display module 20 to encapsulate the edge of the display module 20 with the cover plate 10. When the detecting light irradiates the back surface 201 from the side of the back surface, a first position of the back surface 201 where the optical film 30 is provided and a second position of the back surface 201 where only the encapsulant 40 is provided have different light reflection intensities. The grayscale values of the grayscale images detected by using the AOI technology have a significant difference. The connection between the first position where the optical film 30 is provided and the second position where only the encapsulant 40 is provided is the edge of the display module 20.

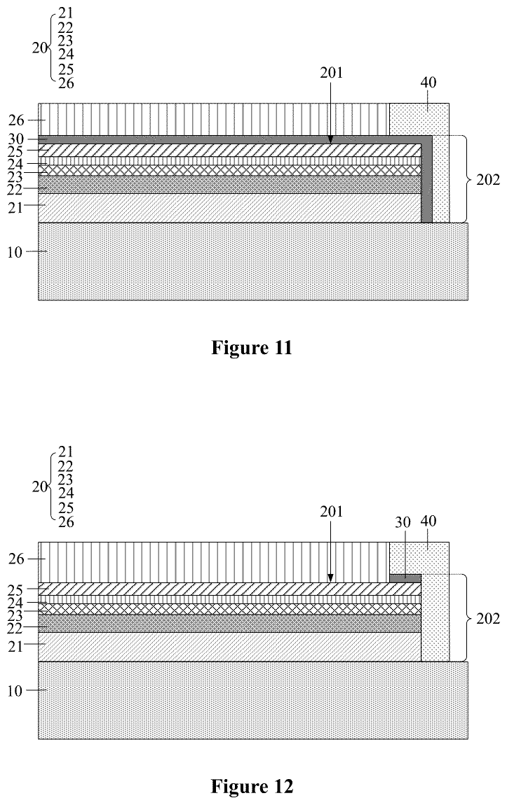

Since the sidewall 202 of the display module 20 is not irradiated by the detecting light, the optical film 30 may alternatively be provided on the back surface 201 and the sidewall 202 of the display module 20. FIG. 11 is a schematic structural diagram of a film structure of a flat display panel according to another embodiment of the present disclosure. Reference is made to FIG. 11, the display panel is a flat display panel, such as a flat screen. The optical film 30 is provided on the back surface 201 of the display module 20 and the sidewall 202 of the display module 20. For operation principles of the above structure, reference may be made to the corresponding embodiment in FIG. 10, which is not be described again here.

In an embodiment, referring to FIG. 12, which is a schematic diagram of the film structure of a flat display panel according to another embodiment of the present disclosure, the display panel is the flat display panel, such as a flat screen. In this embodiment, the optical film 30 covers at least a part of the back surface 201 of the display module 20, and the edge of the optical film 30 is flush with the edge of the display module 20. That is, the edge of the optical film 30 is flush with the connection between the back surface 201 and the sidewall 202 of the display module 20. Similar to the above embodiment, the encapsulant 40 is provided at the edge of the display module 20 to encapsulate the edge of the display module 20 with the cover plate 10. When the detecting light irradiates the back surface 201, at the side of the back surface 201, a first position of the back surface 201 where the optical film 30 is provided and a second position of the back surface 201 where only the encapsulant 40 is provided have different light reflection intensities. The grayscale values of the grayscale images detected by using the AOI technology have a significant difference. The connection between the first position where the optical film 30 is provided and the second position where only the encapsulant 40 is provided is the edge of the display module 20.

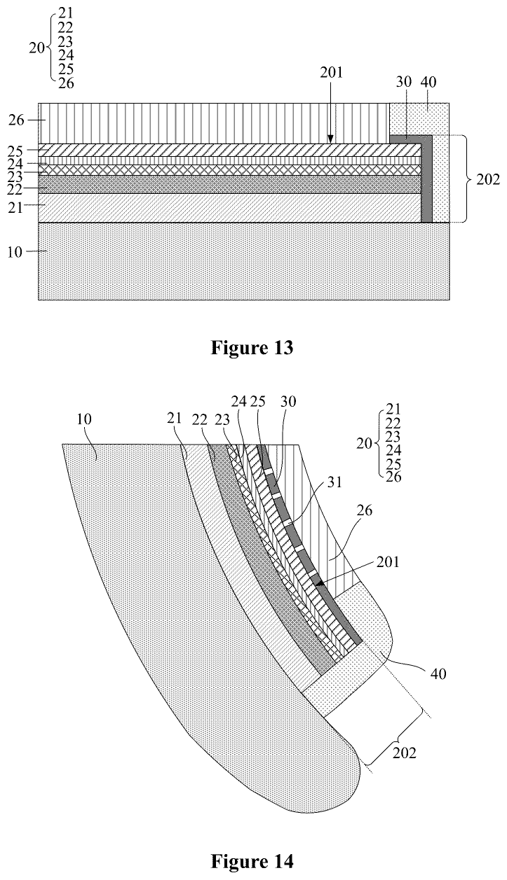

Since the sidewall 202 of the display module 20 is not irradiated by the detecting light, the optical film 30 may alternatively be provided on the back surface 201 and the sidewall 202 of the display module 20. FIG. 13 is a schematic structural diagram of a film structure of a flat display panel according to another embodiment of the present disclosure. Reference is made to FIG. 13, the display panel is a flat display panel, such as a flat screen. In the embodiment, the optical film 30 covers at least a part of the back surface 201 of the display module 20 and covers the sidewall 202 of the display module 20. For operation principles of the above structure, reference may be made to the corresponding embodiment of FIG. 12, which is not described again here.

In some embodiments, when the display panel is a flat display panel, the optical film includes the reflective layer. A position where the reflective layer is provided has large light reflection intensity, the detection device receives more reflected light, and the grayscale value of the corresponding grayscale image is large. A position where the reflective layer is not provided has small light reflection intensity, the detection device receives less reflected light, and the grayscale value of the corresponding grayscale image is small. Therefore, the grayscale values of the grayscale images detected by using the AOI technology are significantly different from each other, and the edge of the display module can be accurately recognized.

In some embodiments, referring to FIG. 8, the reflective layer includes a metal reflective layer or a polyester film. The reflective layer may strongly reflect the light emitted by the detecting light source and improve the light reflection intensity at the position where the reflective layer is provided. The reflective layer includes a metal reflective layer or a polyester film, where the metal reflective layer includes a metal material with high light reflectivity, such as at least one of Ag, Al, Au, and Cu. In an embodiment, an aluminum film is selected as the metal reflective layer. The aluminum film has a high reflectivity from the ultraviolet region to the infrared region. The aluminum film forms a thin aluminum oxide film at a surface exposed to air, and the aluminum oxide file may also protect the film layer. Therefore, the reflective layer including the aluminum film is stable. The reflective layer may alternatively include the polyester film, which is formed by coating on the surface of a white film. The polyester film has a high reflectivity, good processing performance, low cost, and may be used for display modules with various sizes.

In some embodiments, when the optical film is provided on the back surface of the display module, the optical film may be attached to the back surface of the display module by using an optical adhesive. When the optical film is provided on the sidewall of the display module, the optical film may be coated on the sidewall of the display module, and may be an adhesive with high reflectivity, or other liquid or semi-solid coatings, which are given as examples, and the present disclosure is not limited thereto.

In some embodiments, the reflective layer has a reflectivity greater than 95%. The reflective layer is provided on the back surface and/or the sidewall of the display module and the light reflection intensity at the back surface of the display panel is different from the light reflection intensity at the sidewall of the display module, to increase the difference between grayscale values of the grayscale images of the back surface and the sidewall. A greater contrast may cause a more accurate recognition of the edge of the display module. A greater reflectivity of the reflective layer corresponds to a greater light reflection intensity, and a greater grayscale value of the grayscale image, and a more significant difference between the grayscale values of the grayscale images as compared with the position without the reflective layer or the position where diffuse reflection occurs. Therefore, the reflectivity of the reflective layer greater than 95% maximizes the reflectivity at the position where the reflective layer is provided.

In some embodiments, reference is made to FIGS. 2 to 7, the optical film 30 includes a light-absorbing layer. When the detecting light irradiates an object, a part of the light is absorbed, while the other part of light unabsorbed is reflected, scattered, or projected. When the optical film 30 is the light-absorbing layer and the detecting light source irradiates the display module 20, the position where the light-absorbing layer is provided has a strong capability to absorb light, and most of the light is absorbed by the light-absorbing layer and a small part of the light is reflected. Therefore, the grayscale value of the grayscale image corresponding to the position where the light-absorbing layer is provided is small. A position without the light-absorbing layer has a weak capability to absorb light, and the grayscale value of the corresponding grayscale image is large, to increase the difference between grayscale values of the grayscale images of the back surface 201 and the sidewall 202 of the display module 20, to accurately recognize the edge of the display module 20.

In an embodiment, reference is made to FIG. 3, in a case that the optical film 30 (light-absorbing layer) is provided on the back surface 201 of the display module 20, the optical film 30 has a strong light absorption capability, and the grayscale value of the grayscale image (A5) corresponding to the position of the back surface 201 where the encapsulant 40 is provided is small. In contrast, the optical film 30 is not provided on the sidewall 202 of the display module 20, the sidewall 202 has a weak light absorption capability, and the grayscale value of the corresponding grayscale image (A4) is large. Therefore, there is a significant difference between the grayscale values of the grayscale images detected by using the AOI technology at the position of the back surface 201 where the encapsulant is provided and the sidewall 202 of the display module 20, and the edge of the display module can be accurately recognized. Reference is made to FIG. 5, in a case that the optical film is provided on the sidewall 202 of the display module 20, the sidewall 202 has a strong light absorption capability, and the grayscale value of the grayscale image (A4) corresponding to the sidewall 202 is small. In contrast, the optical film is not provided on the back surface 201 of the display module 20, the back surface 201 has a weak light absorption capability, and the grayscale value of the corresponding grayscale image (A5) is large. Therefore, there is a significant difference between the grayscale values of the grayscale images detected by using the AOI technology at the back surface 201 and the sidewall 202 of the display module 20, and the edge of the display module can be accurately recognized. Reference is made to FIG. 7, the optical film 30 is provided on the back surface 201 and the sidewall 202 of the display module 20, which is equivalent to the optical film 30 being provided on both sides of the edge of the display module 20, and the light absorption capabilities on both sides of the edge are enhanced. However, the flatness of the back surface 201 is different from that of the sidewall 202. The flatness of the back surface 201 is higher than the flatness of the sidewall 202, and the light absorption capability of the back surface 201 is weaker than the light absorption capability of the sidewall 202. Therefore, the grayscale value of the grayscale image (A5) corresponding to the back surface 201 is small, and the grayscale value of the grayscale image (A4) corresponding to the sidewall 202 is large. Therefore, there is a significant difference between the grayscale values of the grayscale images detected by using the AOI technology at the back surface 201 and the sidewall 202 of the display module 20, and the edge of the display module can be accurately recognized.

In some embodiments, referring to FIG. 8, the optical film 30 is a light-absorbing layer. The light-absorbing layer covers at least a part of the back surface 201 of the display module 20, and the edge of the light-absorbing layer is flush with the edge of the display module 20.

In an embodiment, the light-absorbing layer may cover at least a part of the back surface 201 of the display module 20, and the edge of the light-absorbing layer is flush with the edge of the display module 20. That is, the edge of the reflective layer is flush with the connection between the back surface 201 and the sidewall 202 of the display module 20. The position where the light-absorbing layer is provided has a strong light absorption capability. The sidewall 202 of the display module 20 is not provided with the light-absorbing layer, and has a weak light absorption capability. With the above structure, when the detecting light source irradiates the display panel, the position of the back surface 201 of the display module 20 where the light-absorbing layer is provided and the sidewall 202 of the display module 20 have different light absorption capabilities, which causes a significant difference between the grayscale values of the grayscale images detected by using the AOI technology at the position of the back surface 201 where the light-absorbing layer is provided and the sidewall 202 of the display module 20. The grayscale value of the grayscale image corresponding to the sidewall 202 is larger, and the grayscale value of the grayscale image corresponding to the back surface 201 is small. The difference between the grayscale values is large, and the edge of the display module 20 can be accurately recognized.

It is to be noted that, the range of the part of the back surface 201 of the display module 20 covered by the light-absorbing layer is not limited in the embodiments of the present disclosure, but the edge of the light-absorbing layer needs to be flush with the edge of the display module 20 to facilitate comparison with the sidewall 202 where the reflective layer is not provided.

In some embodiments, FIG. 14 is a schematic structural diagram of a film structure along the AA′ direction of the display panel shown in FIG. 1 according to another embodiment of the present disclosure. Referring to FIG. 14, the optical film 30 covering the back surface 201 of the display module 20 is provided with multiple opening structures 31 at a display region of the display panel.

The display module 20 includes a display functional structure, which emits light under the control of electrical signals and generates heat. The heat may be dissipated through the back surface 201 of the display module 20 to avoid overheating of the display panel. However, the optical film 30 covering the back surface 201 of the display module 20 may affect the heat dissipation of the display module 20. In order to reduce the possibility that the optical film 30 covering the back surface 201 of the display module 20 affects the heat dissipation of the display module 20, the optical film 30 covering the back surface 201 of the display module 20 is provided with multiple opening structures 31 at the display region of the display panel to increase the heat dissipation of the back surface 201. The heat generated by the display functional structure in the display region is dissipated outward through the opening structures 31 to avoid insufficient heat dissipation of the display module.

It is to be noted that, a shape, quantity, and arrangement of the opening structures are not limited in the embodiments of the present disclosure, as long as the heat dissipation the display module can be improved. The above embodiments are only described as examples.

In some embodiments, referring to FIGS. 4 and 5, the optical film 30 in FIGS. 4 and 5 includes a light-absorbing layer, the side of the display panel is bent toward the back surface 201, and the light-absorbing layer covers the sidewall 202 of the display module 20.

The side of the display panel is bent toward the back surface 201. For example, the display panel is a curved screen having a curvature. In a case that the display panel is of this type, the light-absorbing layer may cover only the sidewall 202 of the display module 20. Since the side of the display panel is bent toward the back surface 201, the detecting light, when irradiating the back surface 201 of the display module 20 from the side of the back surface 201 of the display module 20, may also irradiate the sidewall 202 of the display module 20. The sidewall 202 of the display module 20 is covered with the light-absorbing layer, and has a strong light absorption capability, and most of the light emitted by the detecting light source is absorbed by the light-absorbing layer, and the grayscale value of the grayscale image of the sidewall 202 is small. The back surface 201 of the display module 20 is not provided with the light-absorbing layer, and has a weak light absorption capability, and the grayscale value of the grayscale image of the back surface 201 is relatively large. Therefore, there is a significant difference between the grayscale values of the grayscale images detected by using the AOI technology at the back surface 201 and the sidewall 202 of the display module 20. Accordingly, the edge of the display module 20 can be accurately recognized.

In an embodiment, reference is made to FIGS. 2 to 7, in an application scenario where the optical film 30 includes a light-absorbing layer and the side of the display panel is bent toward the back surface 201, the contrast between the grayscale images of the back surface 201 and the sidewall 202 of the display module 20 may be increased by various manners, including: arranging the light-absorbing layer on the back surface 201 of the display module 20, arranging the light-absorbing layer on the sidewall 202 of the display module 20, or arranging the light-absorbing layer on both the back surface 201 and the sidewall 202 of the display module 20. The above various manners of arranging the light-absorbing layer increase the difference between grayscale values of the grayscale images of the back surface 201 and sidewall 202 of the display module 20 to accurately recognize the edge of the display module 20.

In some embodiments, the display panel is a flat display panel, such as a flat screen, and the side of the display panel is a flat structure. Reference is made to FIGS. 10 to 14, the optical film includes a light-absorbing layer. Similar to the optical film including a reflective layer in the above embodiment, the detecting light does not irradiate the sidewall 202 of the display module 20. Therefore, the light-absorbing layer may be provided on only the back surface 201 of the display module 20 as shown in FIG. 10; or the light-absorbing layer may be provided on both the back surface 201 and the sidewall 202 of the display module 20 as shown in FIG. 11; or as shown in FIG. 12, the light-absorbing layer covers at least a part of the back surface 201 of the display module 20, and the edge of the light-absorbing layer is flush with the edge of the display module 20; or the light-absorbing layer covers at least a part of the back surface 201 of the display module 20 and covers the sidewall 202 of the display module 20. The above-mentioned various manners increase the difference between the grayscale values of the grayscale images of the back surface 201 and the sidewall 202 of the display module 20, to facilitate recognition of the edge of the display module 20.

In some embodiments, the light-absorbing layer is doped with black light-absorbing particles. Since the black color does not reflect light and has the strongest absorption capability, the light-absorbing layer may be doped with black light-absorbing particles. The light emitted by the detecting light source may not be reflected when it encounters the black light-absorbing particles in the light-absorbing layer. Therefore, the reflective capability at the position where the light-absorbing layer is provided is reduced. Less light is reflected, and the detection equipment receives less reflected light, resulting in a small grayscale value of the obtained grayscale image. The position where the light-absorbing layer is not provided has strong reflective capability, and the grayscale value of the obtained grayscale image is large. Therefore, the difference between grayscale values of the grayscale images of the back surface and the sidewall of the display module can be increased to accurately recognize the edge of the display module.

In some embodiments, a base material of the light-absorbing layer includes an organic polymer material. When preparing the light-absorbing layer, the organic polymer material may be used as the base material, since the organic polymer material is capable of absorbing light, and has good water and oxygen barrier properties due to its capability of preventing external water and oxygen from entering the display module. The organic polymer material also has good processing properties and mature preparation process, and is applicable to display modules with various sizes. It is to be noted that, the material of the light-absorbing layer is not limited in the embodiments of the present disclosure, and the above are only examples for description.

In some embodiments, a thickness of the optical film ranges from 2 um to 3 um. The optical film needs to be provided on the back surface and/or the sidewall of the display module, and the light reflection intensities of the display panel at the back surface and sidewall of the display module are different. Therefore, there is a requirement for the thickness of the optical film. In a case that the optical film is too thick, the original structure of the display panel may be affected, resulting in a thick overall film structure. In a case that the optical film is too thin, the light reflection intensity at the back surface and sidewall of the display module may not be changed effectively, the contrast between the grayscale images of the back surface and the sidewall of the display module may not be increased. Therefore, the thickness of the optical film should be within an appropriate range. In an embodiment, the thickness of the optical film ranges from 2 um to 3 um. In this thickness range, the light reflection intensity at the back surface and the sidewall of the display module can be effectively changed without affecting the original structure of the display panel. In some other embodiments, different thickness ranges of the optical film may be configured for different display panels. The thickness range of the optical film may be set according to the actual situation. The above range in the embodiments of the present disclosure is only an example.

In some embodiments, referring to FIG. 2, the display module 20 includes a display functional structure and a supporting layer 25. The display functional structure is located between the cover plate 10 and the supporting layer 25. The optical film 30 is provided on the sidewall 202 of the display module and/or a surface of the supporting layer 25 20 facing away from the display functional structure.

In an embodiment, the display functional structure shown in FIG. 2 includes an optical adhesive layer 21, a polarizer 22, a display light-emitting layer 23 and an adhesive layer 24. The display functional structure is located between the cover plate 10 and the supporting layer 25. The display functional structure is configured to emit light outwardly. The optical film 30 is provided on the sidewall 202 of the display module 20 and/or a surface of the supporting layer 25 facing away from the display functional structure. The optical adhesive layer 21 is configured to be connected and fixed to the cover plate 10. In an embodiment, the optical adhesive layer 21 may be OCA (Optically Clear Adhesive), which is colorless and transparent, has a light transmittance of greater than 90%, has a good bonding strength, can be cured at room or medium temperature, and has small curing shrinkage. The display light-emitting layer 23 is capable of emitting light to the light-exiting side, and the polarizer 22 is capable of eliminating the reflection of external light. The adhesive layer 24 and the supporting layer 25 are located on a side of the back surface 201 of the display module 20, for improving the strength of the display module 20. The display light-emitting layer 23 further includes a variety of film structures, such as a light-emitting layer, at least one of an electron injecting layer, an electron transporting layer, a hole blocking layer, an electron blocking layer, an air transporting layer, and a hole injecting layer, to improve carrier transporting performance.

In some other embodiments, the display module further includes other film structures, such as a shielding layer, or the like. It is to be noted that, the film structures in the display module are not limited in the embodiments of the present disclosure, and may be set according to actual needs.

In some embodiments, referring to FIG. 2, the display module 20 further includes a protective layer 26 located on a side of the supporting layer 25 away from the display functional structure. The projection of the edge of the protective layer 26 on the cover plate 10 is located within the projection of the supporting layer 25 on the cover plate 10. There is a gap D between the edge of the protective layer 26 and the edge of the supporting layer 25 on a same side of the display panel. The optical film 30 is provided on the surface of the supporting layer 25 away from the display functional structure at a position within the gap between the edge of the protective layer 26 and the edge of the supporting layer 25.

The protective layer 26 of the display module 20 is located on the side of the supporting layer 25 away from the display functional structure. In an embodiment, a material of the protective layer 26 may be composite buffer foam. The protective layer 26 is configured to protect the display panel and improve the overall performance of the display panel by providing shock absorption, impact-resistance function, and the like. The projection of the edge of the protective layer 26 on the cover plate 10 is within the projection of the supporting layer 25 on the cover plate 10 on a same side of the cover plate 10. That is, the length of the protective layer 26 is shorter than the length of the supporting layer 25. There is a distance D between the edge of the protective layer 26 and the edge of the supporting layer 25 on the same side of the display panel. Since the display panel needs to be connected and fixed with the middle frame of the display device, and the display panel should be fitted into the middle frame, the length of the protective layer 26 is required to be configured in a manner that the protective layer 26 is fitted into the middle frame. When preparing the protective layer 26, due to process limitations, the required length of the protective layer 26 may not be achieved and is often exceeded, resulting in failure in fitting the protective layer in the middle frame. Therefore, the length of the protective layer 26 is generally shorter than the supporting layer 25 and other films. The optical film 30 is provided on the surface of the supporting layer 25 facing away from the display functional structure at the position of the gap between the edge of the protective layer 26 and the edge of the supporting layer 25. Under irradiating of the detecting light source, the position of the gap between the edge of the protective layer 26 and the edge of the supporting layer 25 where the optical film 30 is provided has a different light reflection intensity from the sidewall 202 of the display module.

In an embodiment, reference is made to FIG. 3, which provides seven grayscale images A1-A7. Different film materials have different light reflection intensities. B represents the grayscale image (including A1 and A2) corresponding to a part of the cover plate 10 without the encapsulant 40. Since the cover plate 10 is bent toward the back surface 201, the cover plate has different light reflection intensities. There is a difference in reflectivity between the flat part and the curved part, therefore the grayscale value of the grayscale image corresponding to the flat part is different from that of the curved part. C represents the grayscale image (including A3-A6) corresponding to a part of the display panel where the encapsulant 40 is provided. At the position corresponding to A3, the cover plate 10 is behind the encapsulant 40. At the position corresponding to A4, the display module 20 is behind the encapsulant 40. At the position corresponding to A5, the optical film 30 is behind the encapsulant 40. A7 represents the grayscale image detected by using AOI corresponding to the protective layer 26.

A display device is further provided according to the present disclosure, which includes the display panel in any one of the above embodiments. Therefore, the display device has features of the display panel according to the embodiments of the present disclosure, and can achieve beneficial effects of the display panel according to the embodiments of the present disclosure. For the same content, reference can be made to the above description of the display panel according to the embodiments of the present disclosure, which will not be described again.

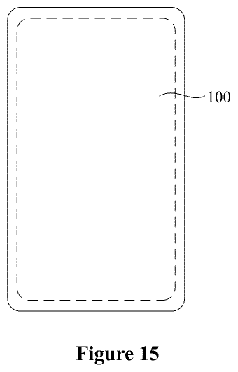

In an embodiment, FIG. 15 is a schematic structural diagram of a display device according to an embodiment of the present disclosure. As shown in FIG. 15, the display device according to the embodiment of the present disclosure includes the display panel 100 according to any one of the above embodiments of the present disclosure. The embodiment shown in FIG. 15 only takes a mobile phone as an example to illustrate the display device. Herein the display device can be any electronic product with a display function, including but not limited to: a mobile phone, a television, a notebook computer, a desktop monitor, a tablet computer, a digital camera, a smart bracelet, smart glasses, a vehicle monitor, medical equipment, industrial control equipment, a touch interactive terminal, or the like, which are not limited in the embodiments of the present disclosure.

Herein the display device includes the above-mentioned display panel, therefore the display device can also solve the same problems as the above-mentioned display panel and achieve a same effect, which will not be described again here.

It should be noted that, the relationship terms such as “first”, “second” and the like are only used herein to distinguish one entity or operation from another, rather than to necessitate or imply that an actual relationship or order exists between the entities or operations. Furthermore, the terms such as “include”, “comprise” or any other variants thereof means to be non-exclusive. Therefore, a process, a method, an article or a device including a series of elements include not only the disclosed elements but also other elements that are not clearly enumerated, or further include inherent elements of the process, the method, the article or the device. Unless expressively limited, the statement “including a . . . ” does not exclude the case that other similar elements may exist in the process, the method, the article or the device other than enumerated elements.

According to the description of the disclosed embodiments, can implement or use the present disclosure. Various modifications made to these embodiments, and the general principle defined herein may be implemented in other embodiments of the present disclosure. Therefore, the present disclosure is not limited to the embodiments described herein but conforms to a widest scope in accordance with principles and novel features disclosed in the present disclosure.

1. A display panel, comprising:
a cover plate and a display module; wherein
the cover plate is located on a light-exiting side of the display module;
an optical film is provided on a back surface of the display module and/or a sidewall of the display module;
an encapsulant is provided at an edge of the display module to encapsulate the edge of the display module with the cover plate; and
the optical film causes a light reflection intensity at the back surface of the display module to be different from a light reflection intensity at the sidewall of the display module.

2. The display panel according to claim 1, wherein the optical film comprises a reflective layer.

3. The display panel according to claim 2, wherein the reflective layer covers at least a part of the back surface of the display module, and an edge of the reflective layer is flush with the edge of the display module.

4. The display panel according to claim 2, wherein the reflective layer covers at least a part of the back surface of the display module and covers the sidewall of the display module.

5. The display panel according to claim 2, wherein a side of the display panel is bent toward the back surface of the display module; and the reflective layer covers the sidewall of the display module.

6. The display panel according to claim 2, wherein the reflective layer comprises a metal reflective layer or a polyester film.

7. The display panel according to claim 2, wherein a reflectivity of the reflective layer is greater than 95%.

8. The display panel according to claim 1, wherein the optical film comprises a light-absorbing layer.

9. The display panel according to claim 8, wherein the light-absorbing layer covers at least a part of the back surface of the display module, and an edge of the light-absorbing layer is flush with the edge of the display module.

10. The display panel according to claim 3, wherein the optical film covering the back surface of the display module is provided with a plurality of opening structures in a display region of the display panel.

11. The display panel according to claim 9, wherein the optical film covering the back surface of the display module is provided with a plurality of opening structures in a display region of the display panel.

12. The display panel according to claim 8, wherein a side of the display panel is bent toward the back surface of the display module; and the light-absorbing layer covers the sidewall of the display module.

13. The display panel according to claim 8, wherein the light-absorbing layer is doped with black light-absorbing particles.

14. The display panel according to claim 8, wherein a base material of the light-absorbing layer comprises an organic polymer material.

15. The display panel according to claim 1, wherein a thickness of the optical film ranges from 2 um to 3 um.

16. The display panel according to claim 1, wherein the display module comprises a display functional structure and a supporting layer; the display functional structure is located between the cover plate and the supporting layer; and the optical film is provided on the sidewall of the display module and/or a surface of the supporting layer facing away from the display functional structure.

17. The display panel according to claim 16, further comprising a protective layer, located on a side of the supporting layer away from the display functional structure;
wherein a projection of an edge of the protective layer on the cover plate is located within a projection of the supporting layer on the cover plate; there is a gap between the edge of the protective layer and the edge of the supporting layer on a same side of the display panel; the optical film is provided on a surface of the supporting layer facing away from the display functional structure at a position of the gap between the edge of the protective layer and the edge of the supporting layer.

18. A display device, comprising a display panel, wherein the display panel comprises:
a cover plate and a display module; wherein
the cover plate is located on a light-exiting side of the display module;
an optical film is provided on a back surface of the display module and/or a sidewall of the display module;
an encapsulant is provided at an edge of the display module to encapsulate the edge of the display module with the cover plate; and
the optical film causes a light reflection intensity at the back surface of the display module to be different from a light reflection intensity at the sidewall of the display module.
